(19) United States
(12) Patent Application Publication
(10) Pub. No.: US 2024/0012027 A1
(43) Pub. Date: Jan. 11, 2024

(54) PROBE HEAD WITH AN IMPROVED CONTACT BETWEEN CONTACT PROBES AND METALLIZED GUIDE HOLES

(71) Applicant: TECHNOPROBE S.P.A., Cernusco Lombardone (LC) (IT)

(72) Inventor: Raffaele VALLAURI, Cernusco Lombardone (LC) (IT)

(73) Assignee: TECHNOPROBE S.P.A., Cernusco Lombardone (LC) (IT)

(21) Appl. No.: 18/252,142

(22) PCT Filed: Nov. 10, 2021
(86) PCT No.: PCT/EP2021/081290

§ 371 Date: May 8, 2023

(30) Foreign Application Priority Data
Nov. 12, 2020 (IT) 102020000027149

(51) Int. Cl. G01R 1/073

(52) U.S. Cl. CPC G01R 1/07314; G01R 1/07357

(57) ABSTRACT

A probe head for testing the operation of a device under test is disclosed. The probe head has a plurality of contact probes including a body extending along a longitudinal axis adapted to contact respective contact pads and having a substantially square or rectangular-shaped cross section, and a guide lying in a plane and provided with guide holes having a substantially square or rectangular-shaped cross section for slidingly housing the contact probes. In the plane of the guide the cross section of the guide holes and the cross section of the contact probes are rotated relative to each other around the longitudinal axis and have respective different orientations with respect to a reference system in the plane, so that an edge of the body is mechanically interfering with a corresponding wall of the guide holes The probe head also has a conductive portion formed at the guide and/or formed at another guide of the probe head being adapted to contact and short-circuit a corresponding group of contact probes.

### FIELD OF APPLICATION

The present disclosure relates to a probe head for testing electronic devices integrated on a semiconductor wafer, and the following description is made with reference to this application field with the only purpose of simplifying the exposition thereof.

### PRIOR ART

As it is well known, a probe head is essentially an electronic device adapted to electrically connect a plurality of contact pads of a microstructure, in particular an electronic device integrated on a semiconductor wafer, with corresponding channels of a testing apparatus that performs the functionality testing thereof.

This test is particularly useful for detecting and isolating defective circuits as early as in the production phase. Normally, probe heads are therefore used for the test of the circuits integrated on wafers before cutting and assembling them inside a containment package.

A probe head essentially comprises a plurality of movable contact probes retained by at least one pair of supports or guides that are substantially plate-shaped and parallel to each other. Said plate-shaped supports are provided with suitable guide holes and are arranged at a certain distance from each other in order to leave a free area or air gap for the movement and possible deformation of the contact probes, which are usually made of wires of special alloys with good electric and mechanical properties.

The contact probes generally extend between a first end portion, which is adapted to contact the contact pads of the device under test, and a second end portion, which is adapted to contact a space transformer, or a printed circuit board (PCB) associated with the probe head.

The correct operation of a vertical probe head is basically linked to two parameters: the vertical movement (overtravel) of the contact probes and the horizontal movement (scrub) of the contact tips of said contact probes. All these features should be evaluated and calibrated in the manufacturing step of a probe head, and the proper electrical connection between probes and device under test should always be ensured.

In an ever-increasing number of applications, for instance in high-frequency applications, at least one of the guides of the probe head has a conductive portion (in particular a metallization) with the purpose of electrically connecting (i.e. short-circuiting) specific groups of contact probes with each other, thus forming a common conductive plane for said groups of probes. In this way, it is possible to improve the frequency performance of the probe head and to carry high frequency signals with low noise.

In order to obtain a good electric connection between the contact probes and said conductive portion, a metallization of the walls of the guide holes which house the probes to be short-circuited is also generally provided. In this case, during the test of a device, the electric connection between contact probe and conductive portion of the guide occurs through a sliding contact between the wall of the contact probe and the wall of the metallized guide hole.

It is known, however, that it is often not possible to ensure an efficient electrical connection between probe and metallization, resulting in an unacceptable limitation of the overall performance of the probe head. In other words, it is not always possible to ensure a proper sliding contact between the contact probes and the walls of the guide holes, so that the frequency performance of the probe head is often limited.

The technical problem of the present invention is to provide a contact probe having functional and structural features such as to overcome the limitations and drawbacks still affecting the known solutions, in particular able to ensure an optimal sliding contact between contact probes and walls of the guide holes that house them.

### SUMMARY OF THE INVENTION

The solution idea underlying the present invention is to provide a probe head having guide holes that are suitably rotated with respect to the contact probes therein housed, so as to ensure an efficient contact between the body of the probes (in particular at least one edge thereof) and walls (in particular metallized walls) of the guide holes. In particular, the relative rotation of the cross sections of the contact probes and of the guide holes causes them to assume respective different orientations with respect to the plane of the guide, so that the rotated guide holes are mechanically interfering with the contact probes housed therein during the test of the electronic device. Thanks to the configuration adopted, the sliding contact with metallized walls of the guide hole is always ensured during the movement of the probe in the test phase, even in the presence of a movement of the guides. In particular, the contact is very efficient though maintaining the conventional dimensional ratios between probe and hole, so as not to have interlocking problems, ensuring the sliding of the probes and the sliding contact, an edge of the probe body always remaining in contact with a wall of the hole.

Based on this solution idea, the above technical problem is solved by a probe head for testing the operation of a device under test, the probe head comprising a plurality of contact probes comprising a body extending along a longitudinal axis between respective end portions adapted to contact respective contact pads and having a substantially square or rectangular cross section, and at least one guide lying in a plane and provided with guide holes for slidingly housing the contact probes, the guide holes having a substantially square or rectangular-shaped cross section, wherein, in the plane of the guide, the cross section of the guide holes and the cross section of the contact probes therein housed are rotated relative to each other around the longitudinal axis and have respective different orientations with respect to a reference system in said plane, so that at least one edge of the body is mechanically interfering with a corresponding wall of the guide holes, and wherein the probe head further comprises a conductive portion formed at the guide and/or formed at another guide of the probe head, said another guide comprising respective guide holes, said conductive portion including at least one group of guide holes and being configured to contact and short circuit a corresponding group of contact probes that are housed in said group of holes and are adapted to carry a certain type of signal.

In this way, the electric contact is improved. Preferably, the guide comprising the conductive plate is also the guide having the rotated holes, but it is not excluded that the probe head may also comprise another guide, whose holes are suitably rotated as indicated; according to the present disclosure, there is at least one guide provided with a conductive portion and at least one guide provided with rotated holes, which may be the same guide or a different one.

More particularly, the invention comprises the following additional and optional features, taken singularly or in combination if needed.

According to an aspect of the present invention, all of the edges of the probe body may be mechanically interfering with corresponding walls of the guide holes.

According to another aspect of the present invention, the cross section of the guide holes and the cross section of the contact probes may have a same shape, selected from a square or rectangular shape, with different dimensions.

According to another aspect of the present invention, the guide holes may be rotated with respect to the contact probes by an angle comprised between 5° and 30°.

According to another aspect of the present invention, the at least one conductive portion may cover at least one portion of at least one wall of the guide holes of said group of holes, thus forming a metallized portion which the edge of the probe body is adapted to contact.

Preferably, the entire wall of the guide holes may be covered by the conductive portion.

According to another aspect of the present invention, the guide may be a lower guide of the probe head, namely the closest guide to the device under test when the test is performed.

According to another aspect of the present invention, the probe head may further comprise an upper guide separated by the lower guide by an air gap and provided with respective guide holes, the lower guide being the closest to the device under test when the test is performed.

More particularly, the lower guide and the upper guide may be shifted from each other, resulting in an offset of a first end portion of the contact probes with respect to a second and opposite end portion.

According to another aspect of the present invention, the guide holes of the upper guide and the contact probes may have, in the cross section in the plane of the guide, a same orientation with respect to the reference system in said plane, i.e. they are not rotated with respect to each other.

According to another aspect of the present invention, the probe head may comprise a first lower guide and a second lower guide, wherein the conductive portion is formed in at least one of said first lower guide or said second lower guide, and wherein in the plane of at least one of said first lower guide and said second lower guide the cross section of the guide holes and the cross section of the contact probes therein housed are rotated relative to each other around the longitudinal axis and have respective different orientations with respect to a reference system in said plane, so that at least one edge of the probe body is mechanically interfering with a corresponding wall of the guide holes.

According to another aspect of the present invention, the conductive portion may be arranged on a face of the lower guide.

Furthermore, the conductive portion may be in the form of a plurality of metallizations, which are electrically insulated from each other and configured to form a plurality of respective conductive planes for groups of contact probes.

Finally, in a particular aspect, the guide may comprise guide holes and contact probes whose cross sections are not rotated relative to each other and thus have a same orientation with respect to the reference system in the plane where the guide lies.

The characteristics and advantages of the probe head according to the invention will be apparent from the description, made hereinafter, of an embodiment thereof, given by way of indicative and non-limiting example, with reference to the enclosed drawings.

### BRIEF DESCRIPTION OF THE DRAWINGS

In the drawings:

FIG. 1 schematically shows a probe head according to the present invention;

FIG. 2 schematically shows a top view of a guide according to the present invention;

FIG. 3 schematically shows a top view of a guide according to an embodiment of the present invention; and

FIGS. 4A-4D show possible embodiments of the present invention.

### DETAILED DESCRIPTION

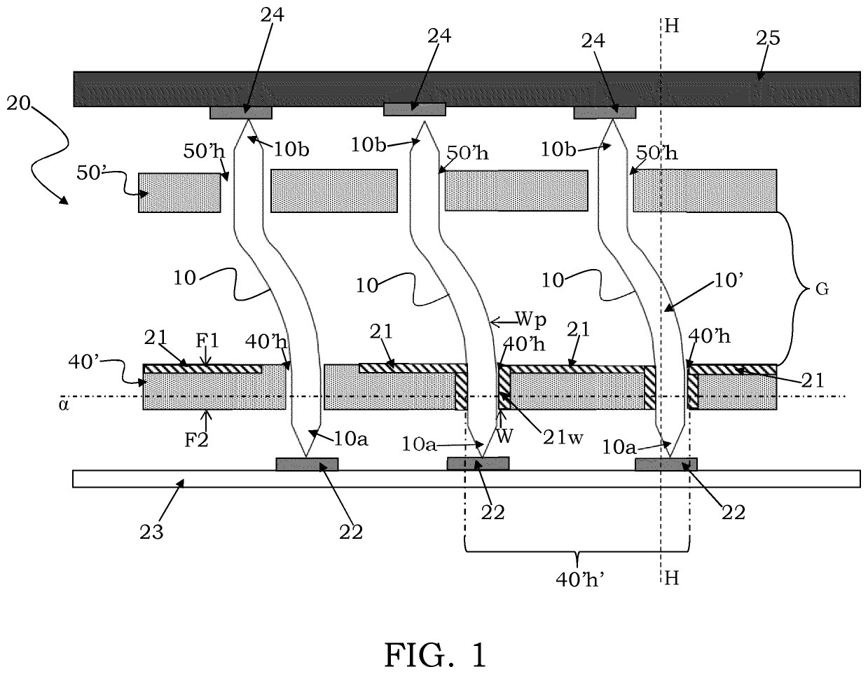

With reference to those figures, and in particular to the example of FIG. 1, a probe head according to the present invention is globally and schematically indicated with 20.

It is worth noting that the figures represent schematic views and are not drawn to scale, but instead they are drawn so as to emphasize the important features of the invention. Moreover, in the figures, the different elements are depicted in a schematic manner, and their shape may vary depending on the application desired. It is also noted that in the figures the same reference numbers refer to elements that are identical in shape or function. Finally, particular features described in relation to an embodiment illustrated in a figure are also applicable to the other embodiments illustrated in the other figures.

The probe head 20 is adapted to connect with an apparatus (not shown in the figures) to perform the test of electronic devices integrated on a semiconductor wafer 23, for instance high-frequency devices.

The probe head 20 comprises a plurality of contact probes 10 slidingly housed in the probe head and adapted to connect the device under test integrated on the semiconductor wafer 23 with the testing apparatus. In order to house the contact probes 10, the probe head 20 comprises at least one guide 40′ provided with guide holes 40′h within which said contact probes 10 are able to slide.

Each contact probe 10 comprises a probe body 10′ extending along a longitudinal axis H-H between a first end portion 10a and a second end portion 10b, which are adapted to contact respective contact pads. By way of example, the first end portion 10a (also called contact tip) is adapted to contact the contact pads 22 of the device under test that is integrated on the semiconductor wafer 23, whereas the second and opposite end portion 10b (also called contact head) is adapted to contact the contact pads 24 of a space transformer or of a printed circuit board (PCB), said latter component being generically identified with the reference number 25. Clearly, though the end portions 10a and 10b in the figures end with a pointed shape, they are not limited thereto, and they may have any shape suitable to the needs and/or circumstances.

The guide 40′ is preferably a lower guide of the probe head 20 and thus, as known in the field, it is close to the first end portion 10a adapted to contact the device under test, i.e. it is closer to the device under test during the test than an upper guide.

The probe body 10′ preferably has a square or rectangular cross section (that is, it is preferably rod-shaped). Therefore, in an embodiment, the probe body 10′ has at least one wall Wp, whose surface is planar and adapted to contact a respective wall of a guide hole.

According to embodiments of the present invention, the contact probe 10 is a probe known in the field as “buckling beam”, i.e. it has a cross section that is constant throughout its length, preferably square or rectangular, wherein the probe body 10′ has a deformation in a position that is substantially central and is adapted to bend and thus to further deform during the test of the device under test.

As it will be described hereinafter, the above deformation of the probe body 10′ is generally obtained through a particular configuration of the probe head 20, namely a so-called shifted-plate type probe head, wherein a pair of guides is first overlapped so as to match the respective guide holes. Afterwards, once the contact probes 10 have been inserted into said guide holes, the guides are spaced apart, thus forming an air gap there between, and then they are shifted, thus causing the above deformation of the probe body 10′.

Generally, the contact probes of the above type are able to further bend during the contact with the pads 22 of the device under test, said bending determining the side movement of the probes in a certain direction, indicated herein as bending direction. The relative shift of the guides determines the bending direction of the contact probes and thus the movement direction of the end portions and of the walls Wp of the probe.

Furthermore, during the bending of the contact probes 10 (in particular during the vertical movement of the probes, indicated in the field as overtravel), a sliding contact between the probe body 10′ and wall of the guide hole occurs.

Therefore, the probe body 10′ comprises a portion adapted to be at least partially inserted into a guide hole 40′h of the guide 40′ of the probe head and, during the movement of the contact probe 10, it performs a contact with said guide hole 40′h, in particular a sliding contact.

It is known in the field that the fixed position of the power and ground signals (due to the layout of the pads of the device under test) and the shape of the probe limit the control of the impedance of the signals within the probe head, as well as they limit the control of the noise caused on the signal probes by other nearby signals, which limits the frequency performance of the probe head.

For this reason, in high-frequency applications (in particular RF applications), the ground probes (and also the power probes) are short-circuited through a metallization on the guide, by short-circuiting probes of a same domain and making the ground contact available inside the probe head to connect possible shields. Furthermore, in case of devices with several ground/power domains on the device then joined on the PCB, the metallization allows to reduce the loop inductance between a power and the respective ground.

For instance, let us consider the case in which a given power of a device under test is contacted by a single probe of the probe head, which is short-circuited with other probes carrying powers that share the same power supply. In this case, when the current of this power meets the metallization that short-circuits all of the probes of this domain, it is divided among all of the short-circuited probes, allowing in this way to reduce inductance and equivalent resistance compared to the case in which said current remains confined to a single probe up to the PCB.

It is therefore evident that the presence of metallizations on the guide, which short-circuit groups of probes and create a common conductive plane, allows reducing noise, and increasing the frequency performance of the probe head.

To this end, according to the present invention, the guide 40′ of the probe head 20 illustrated in FIG. 1 comprises at least one conductive portion 21 (also indicated as conductive plate) which includes and electrically connects to each other the holes of at least one group (indicated with reference number 40′h′) of the guide holes 40′h and which is adapted to contact, and thus to short-circuit, a corresponding group of contact probes, which are adapted to carry a same type of signal, in particular adapted to carry a certain ground domain or power domain or operative signal domain.

For example, the contact probes 10 short-circuited by the conductive portion 21 may be contact probes adapted to carry ground signals, as well as they may be contact probes adapted to carry power signals. In other words, in the probe head 20, the contact probes that are short-circuited with each other thanks to the metallization of the guide 40′ and housed in the group 40′h′ of the guide holes 40′h are adapted to carry a same ground signal or a same power signal, resulting in an increase in the performance of the probe head.

Furthermore, as above mentioned, the short-circuited probes may also be contact probes adapted to carry input/output operating signals between the device under test and the testing apparatus interfaced with the probe head 20, as it happens for instance in the loop-back technique.

In any case, the conductive portion 21 is such as to form a common conductive plane in the probe head.

Obviously, the probe head 20 may comprise any number of conductive portions 21 arranged in any way on the guide or even embedded therein (or arranged on another guide, or there may be more conductive portions on more guides), to carry any type of signal. For instance, the conductive portion may be arranged on an upper face F1 of the guide 40′ (as illustrated in the non-limiting example of FIG. 1), as well as on a lower face F2 thereof, as well as it may be formed inside said guide.

Furthermore, it is possible to provide the presence of a plurality of metallizations, which are electrically insulated from each other and are configured to form a plurality of respective conductive planes for groups of contact probes 10. It is possible to provide for instance a first conductive portion that short-circuits ground probes and a second conductive portion that short-circuits power probes arranged on an opposite face of the guide or even on another guide (such as for instance an intermediate guide not illustrated in the figures), as well as it is possible to provide for many other configurations, as described for instance in the international patent application No. PCT/EP2017/082180 to the Applicant. The method of making this conductive portion is also not limited to a particular one, for example it may be made by depositing conductive material on a ceramic guide.

In other words, the present invention is not limited by the number and/or arrangement of the conductive portions, which may be established based on the needs and/or circumstances.

As above indicated, the guide 40′ is preferably a lower guide, since it is advantageous to perform the short-circuit of the probes as close as possible to the device under test; in some embodiments, the guide may also be an intermediate guide; in some embodiments, the metallization may be made both on the lower guide and on the intermediate guide.

In any case, the presence of the at least one conductive portion 21 allows forming a common conductive plane that electrically connects several contact probes (i.e. the contact probes 10 housed in the group of holes with each other, and that is able to increase the overall performance of the probe head 20, as above indicated.

Furthermore, in some embodiments, the conductive portion 21 covers at least one portion 21w of the walls W of the guide holes of the group 40′h′, forming in this way a metallized portion of the guide hole with which the contact probe 10 is in contact, in particular with which the contact probe performs the above sliding contact.

Preferably, the conductive portion 21 may entirely cover one, some or all of the walls of the guide holes (and thus in this case the metallized portion coincides with the entire wall W of the holes), or, in other embodiments, the conductive portion 21 only partially covers the wall of the guide holes.

In the context of the present invention, the guide 40′ is to be meant as lying in a plane a, which is indicated as plane of the guide.

Given the importance of the conductive portion 21, there is thus the need to ensure an optimal contact between the contact probes 10 and said conductive portion 21 (specifically between probes and metallized walls of the guide holes) during the test of the device, in particular there is the need to always ensure the above sliding contact between contact probe and guide hole.

The present invention will be described in the following based on a non-limiting example in which the guide 40′ is a single lower guide provided with a conductive plate (e.g., the conductive portion 21 as illustrated in FIG. 1), even if, as it will be discussed hereinafter, several configurations may be provided, for instance a configuration in which a second lower guide is associated with the guide 40′ to form a pair of lower guides.

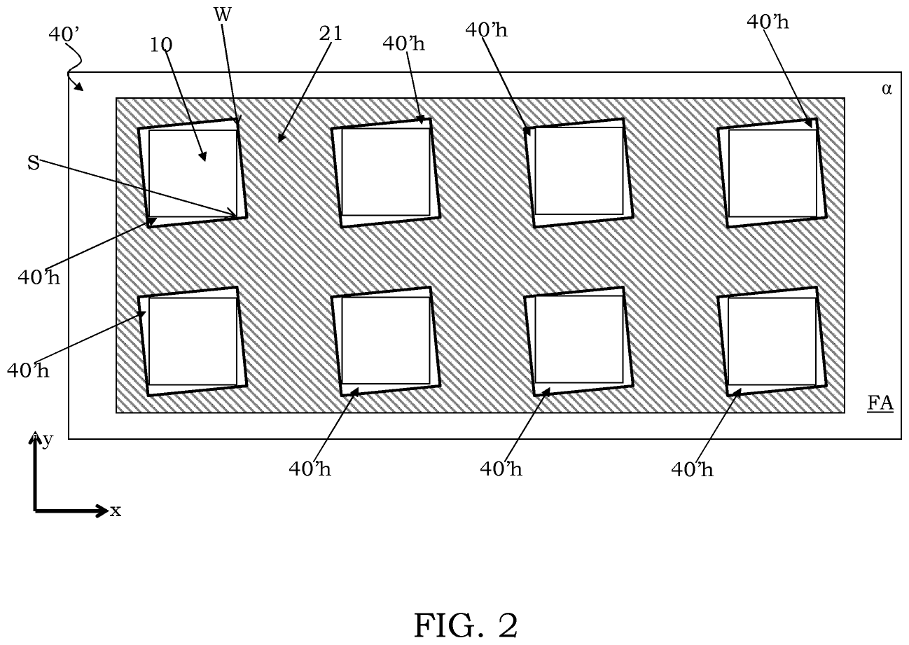

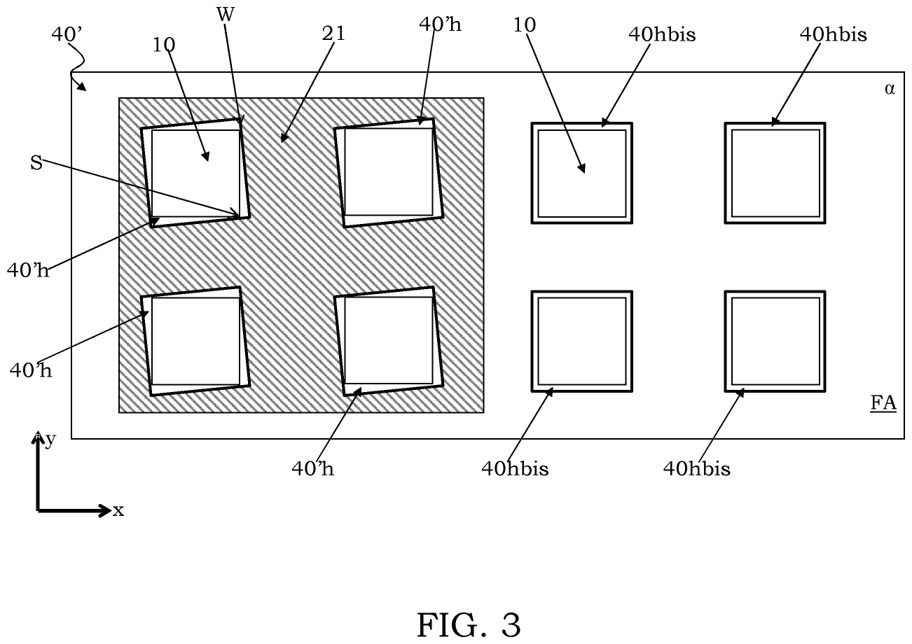

As better illustrated in FIGS. 2 and 3, advantageously according to the present invention, in the plane a of the guide 40′, the cross section of the guide holes 40′h and the cross section of the contact probes 10 therein housed are rotated around the longitudinal axis H-H with respect to each other.

In this way, said cross sections take up respective orientations which are different with respect to a reference system fixed in the plane a of the guide 40′ (for instance a reference system integral with the guide 40′ indicated in the figures as reference system x-y), so that at least one edge S of the probe body is mechanically interfering with a corresponding wall W of the guide holes 40′h.

In the context of the present invention, the x axis corresponds to the horizontal cartesian axis, and the y axis corresponds to the vertical cartesian axis of the adopted reference system.

In the example of FIG. 2, considering the cross section of the contact probes 10 and of the guide holes 40′h in plane a of the guide 40′ (i.e., the cross section along the horizontal dashed line drawn in FIG. 1), the sides of the cross section of the guide holes 40′h are not parallel to the axes of the reference system x-y but are tilted by a certain angle, whereas a pair of sides (in particular the horizontal sides) of the cross section of the contact probes 10 is parallel to the x axis and the other pair of sides (in particular the vertical sides) is parallel to the y axis. In other words, in this example, the cross section of the contact probes 10 is aligned to the indicated reference system and thus it has a null rotation. In this way, the contact probes and the guide holes have the above rotated arrangement with respect to each other. In this way, still considering the cross section of the contact probes 10 and of the guide holes 40′h in the plane a of the guide 40′, the local references of the contact probes and of the guide holes (for instance reference systems having the axes parallel to the sides of the respective cross sections) are differently oriented (rotated) with respect to each other, thus obtaining great advantages, as indicated herein below.

Obviously, the configuration illustrated in the figures is merely indicative and not-limiting of the scope of the present invention, since probes and holes may also have other particular relative orientations, as well as it is possible to use a different reference system; according to the present invention, the orientations of the sections of the contact probes and guide holes, with respect to a given reference system, are different from each other, thus causing the above mechanical interference between contact probe and wall of the guide hole. It is observed that, in the context of the present invention and as known in the field, the term “orientation” indicates the specific orientation of the sides of the cross sections with respect to the axes of a fixed reference, as the reference system x-y of the figures. The longitudinal axis of the contact probes may be seen as the symmetry axis or rotation axis.

In other words, the guide holes 40′h and the contact probes 10 are thus configured so as to ensure that there is always a mechanical interference between the probe body 10′ and one or more walls of said guide holes so as to ensure the desired sliding contact between contact probe and guide hole, the adopted configuration being such that said contact is never lost during the test.

Preferably, all of the edges S of the probe body 10′ are mechanically interfering with corresponding walls W of the guide holes 40′h, so as to further optimize the contact between contact probe and guide hole.

In an embodiment of the present invention, the cross section of the guide holes 40′h has a same shape as the cross section of the contact probes 10. In the example of FIGS. 2 and 3, said cross sections are both square-shaped (and thus said cross sections look like a square inscribed in another rotated square), even though, in other embodiments, they could be rectangular-shaped or could have other suitable shapes.

In general, the guide holes 40′h are rotated with respect to the contact probes 10 by an angle comprised between 5° and 30°.

As shown in FIG. 2, the orientation of the contact probes 10 in the plane of the guide 40′ is substantially identical to that of the contact probes in the traditional probe heads, whereas the sides of the guide holes 40′h of the guide 40′ are suitably tilted to ensure the optimal sliding contact. With respect to the reference system x-y of the figures, the sides of the cross section of the guide holes 40′h are thus oblique, just as they are oblique also with respect to the corresponding sides of the cross section of the contact probes 10.

Obviously, without limitation of the scope of the present invention, it is also possible to devise a complementary situation in which the guide holes are not rotated with respect to the reference of the guide, for instance with respect to the reference system x-y, but the cross sections of the contact probes are rotated; in this latter case, the guide holes may be thought as made traditionally and the probes are mounted rotated with respect to the plane of the guide.

In any case, the term “rotation” or “rotated arrangement” indicates a configuration in which the orientations of the cross sections are rotated with respect to each other regardless of the reference used, in order to ensure the optimal sliding contact as above indicated.

It is thus clear that the arrangement herein illustrated allows improving the quality of the sliding contact between contact probe 10 and metallized wall of the guide hole 40′h, thus solving the problems of the prior art, the sliding against the walls during the bending of the contact probes being always ensured in an optimal manner.

As above indicated, the arrangement between probe and hole herein illustrated is preferably made at the lower guide, and thus at the first end portion 10a of the contact probe 10. The first end portion 10a is the probe portion that is adapted to contact the pads of the device under test, and, in the contest of the present invention, it is thus the probe portion that is closest to the device under test during the normal operation of the probe head 20 (e.g., during the test). In other words, the skilled person certainly knows that the term “first end portion” 10a indicates the probe portion that is closest to the device under test, ending with the contact tip, and also comprising a probe part that is possibly housed in the lower guide 40′. This embodiment is particularly advantageous since it is preferable to short-circuit the contact probes as close as possible to the device under test, in order to obtain the best frequency performance.

Still with reference to FIG. 1, in an embodiment of the present invention, the probe head 20 also comprises an upper guide 50′ separated from the lower guide 40′ by an air gap G, said upper guide 50′ being suitably offset or shifted from the lower guide 40′ (i.e., the guide holes of the respective guides are shifted from each other along the longitudinal axis) in order to form the deformation of the probe body 10′. The upper guide 50′ comprises a plurality of guide holes 50′h, corresponding to the guide holes 40′h of the lower guide 40′, adapted to slidingly house the contact probes 10.

In the non-limiting example of FIG. 1, the probe head 20 is a the vertical-probe head, wherein the first end portion 10a of the contact probes 10 is adapted to contact the contact pads 22 of the device under test that is integrated on the semiconductor wafer 23, whereas the second end portion 10b is adapted to contact the contact pads 24 of a space transformer or of a PCB 25 associated with the probe head 20.

Although it is preferable to form the conductive portion 21 on the lower guide 40′ for the above indicated reasons, nothing forbids from forming, in addition or as an alternative, the conductive portion on the upper guide 50′ if the circumstances require it, or, as it will be seen hereinafter, on further lower guides associated with the lower guide 40′, even not comprising holes and probes that are rotated with respect to each other.

As above mentioned, the lower guide 40′ and the upper guide 50′ are shifted from each other, defining an offset of the first end portion 10a of the contact probes 10 with respect to the second and opposite end portion 10b.

Furthermore, in an embodiment of the present invention, the guide holes of the upper guide 50′ and the contact probes 10 have, in the cross section in the plane a, a same orientation with respect to the reference system x-y in said plane a (i.e. the guide holes 50′h of the upper guide are not rotated and have a same orientation as the contact probes).

In its general form, as illustrated in FIG. 3, the probe head 20 comprises both contact probes and guide holes arranged rotated with respect to each other and contact probes and guide holes not rotated with respect to each other, for instance in the case of contact probes that do not need to be short-circuited and thus that do not need to be electrically connected to a conductive portion. In other words, in the embodiment of FIG. 3, the guide 40′ also comprises guide holes (indicated as guide holes 40hbis) and contact probes 10 whose cross sections are not rotated with respect to each other and have a same orientation with respect to the reference system x-y in the plane a.

In an embodiment, the probe head 20 may also comprise further guides with respect to what has been previously observed. In this case, the different orientation (i.e., the rotated arrangement) between contact probes and guide holes may be provided even on said further guides, in addition or alternatively to what has been observed for the guide 40′.

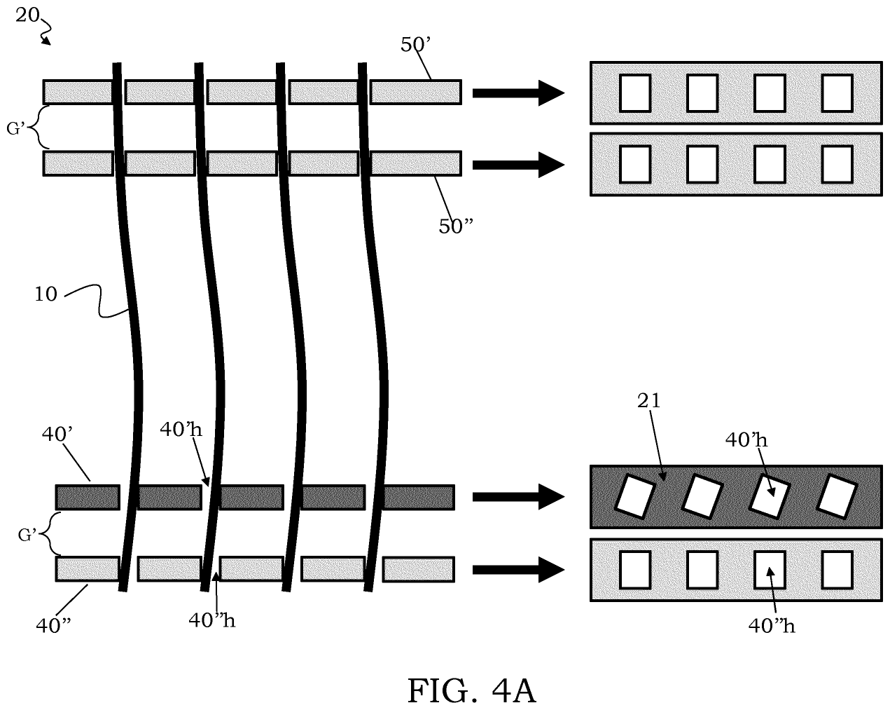

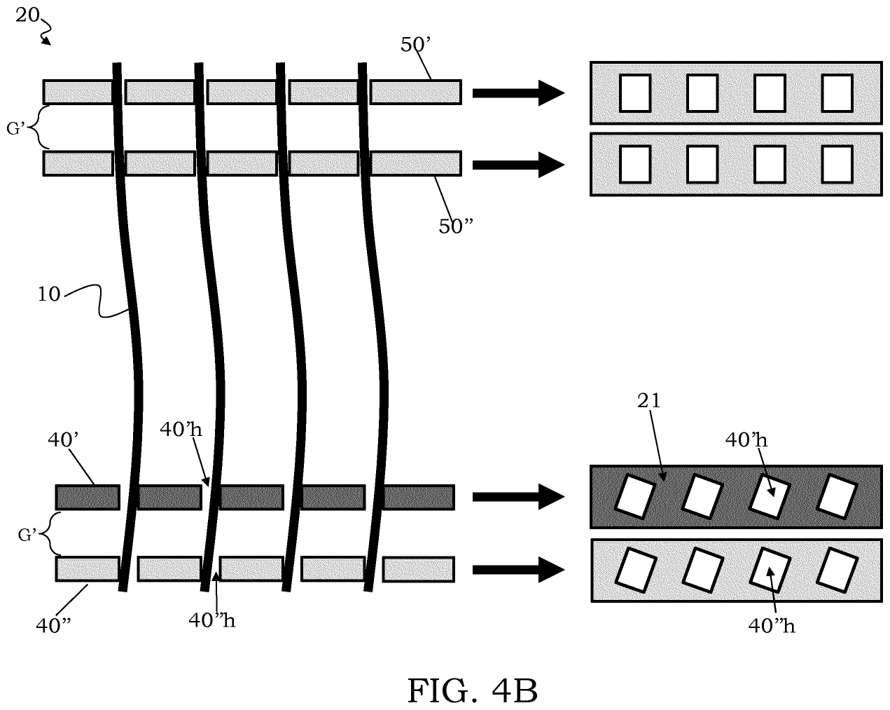

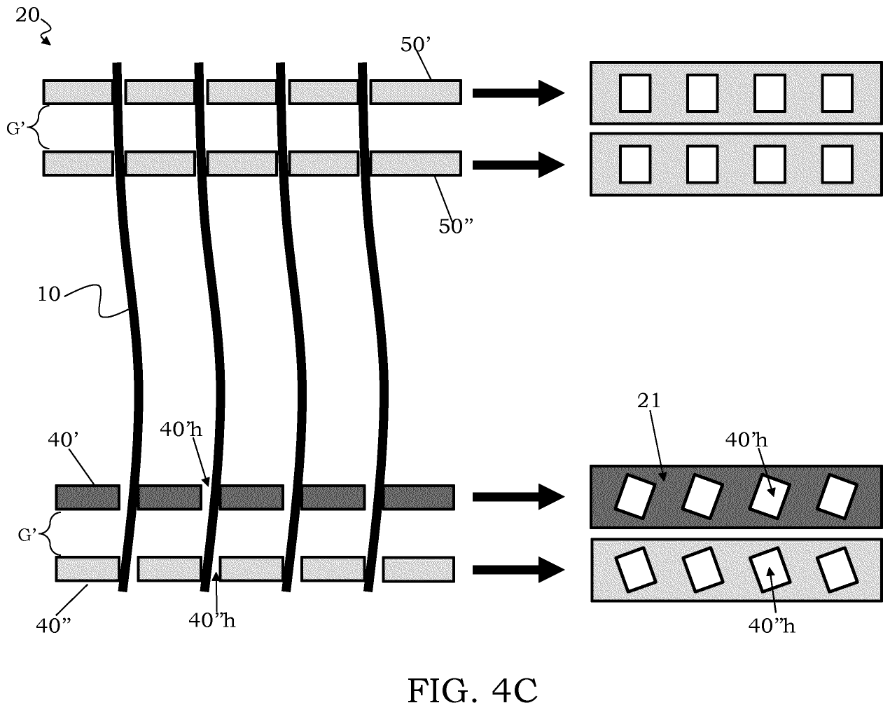

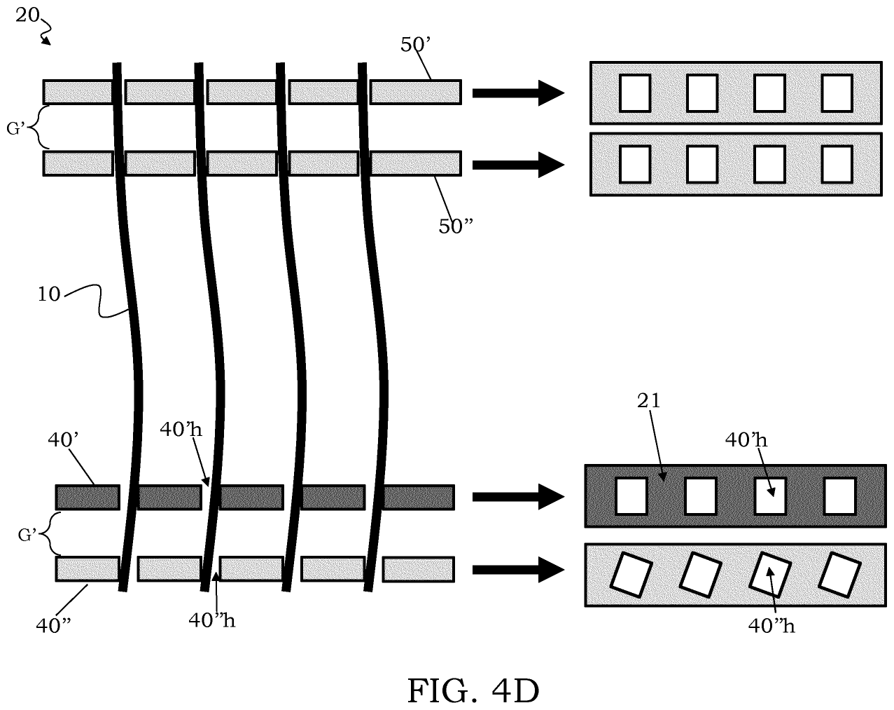

More particularly, as illustrated in FIGS. 4A-4D, in an embodiment of the present invention, the probe head 20 comprises a first lower guide (which may be for instance analogous to the previously described lower guide) and a second lower guide 40″ so as to form a pair of lower guides. Similarly, the probe head 20 may comprise a first upper guide 50′ and a second upper guide 50″ so as to form a pair of upper guides. Said pair of guides are each separated by a proper air gap G′, which is generally less than the air gap G, and they are substantially parallel to each other.

In this case, it is possible to form the conductive portion 21 at the first lower guide 40′, and to configure the relative rotation just of the guide holes 40′h of said first lower guide 40′ (FIG. 4A, which is a preferred exemplary embodiment). In another embodiment, the second lower guide 40″, i.e. in this non-limiting example the lower guide that is closest to the device under test, may also have guide holes 40″h having a rotation with respect to the orientation of the contact probes 10, said guide holes 40″h having a same orientation as that of the guide holes 40′h of the first lower guide 40′, wherein said second lower guide 40″ does not comprise the conductive portion 21 (FIG. 4B). In another embodiment, the guide holes 40″h of the second lower guide 40″ are rotated but in a different direction with respect to the guide holes 40′h of the first lower guide 40′, for instance in an opposite direction (FIG. 4C). Finally, in another embodiment, the first lower guide 40′ (which comprises the conductive portion 21) includes guide holes 40′h having the same orientation as the contact probes 10 (i.e. not rotated), whereas the guide holes 40″h of the second lower guide 40″ (which does not comprise the conductive portion 21) are rotated with respect to the contact probes 10 (FIG. 4D). In other embodiments (not shown), the conductive portion 21 may be formed also at the second lower guide 40″, where probes are short-circuited in a group of holes indicated as 40″h′.

Obviously, even other configurations are possible and fall within the scope of the present invention, each configuration having as purpose that of improving the stability of the electric contact between contact probe 10 and conductive portion 21 of the guide, through the application of a rotation of the holes of one or more guides, thus obtaining a more efficient mechanical interaction between said contact probe 10 and said conductive portion 21.

In conclusion, the present invention provides a probe head having guide holes that are suitably arranged rotated with respect to the contact probes therein housed, so as to ensure an efficient contact between the body of the probes (in particular at least one edge thereof) and walls (in particular metallized walls) of the guide holes. In particular, the relative rotation of the cross sections of the contact probes and of the guide holes causes them to assume respective different orientations with respect to the plane of the guide, so that the rotated guide holes are mechanically interfering with the contact probes housed therein during the test of the electronic device. Thanks to the configuration adopted, the sliding contact of the probe with metallized walls of the guide hole is always ensured during the movement of the probe in the test phase, even in the presence of a movement of the guides. In particular, the contact is very efficient though keeping the conventional dimensional ratios between probe and hole (i.e., the relative orientation is modified, but not the shape), so as not to have interlocking problems, ensuring the sliding of the probes and the sliding contact, an edge of the probe body always remaining in contact with a wall of the hole.

Advantageously according to the present invention, the above rotated arrangement is thus able to always ensure an optimal sliding contact between contact probe and a metallized hole of the guide, in particular during the movement and the bending of the contact probes which is caused by the pressure of the ends thereof against the pads of the device under test during the test, overcoming in this way all of the problems of the known solutions. The quality of said contact between probe and metallization of the wall of the hole is thus greatly increased, without the risk for the contact to be lost during the test, thus increasing the overall performance of the probe head.

During the test, the contact probe is further subjected to a moment (torque, in particular due to the combination of contact forces acting on the probe) which causes the edges thereof to slightly rotate with respect to the longitudinal axis and thus to further slide against the metallized wall of the hole, still increasing the quality of the contact.

It is finally observed that said rotated arrangement allows always maintaining an electric and mechanical contact even in the presence of movements of the guides during the test and without the risk of the probes getting stuck in the holes, which would occur for instance by reducing the clearances, which instead does not occur according to the present invention.

In this way, suitably according to the present invention, it is possible to efficiently short-circuit groups of contact probes through conductive plates on the guides, so as to improve the frequency performance of the probe head housing said probes. It is thus clear that the probe head of the present invention solves the technical problem and is particularly suitable for the test of high-frequency devices, even in the radio-frequency domains.

Obviously, a person skilled in the art, in order to meet contingent and specific requirements, may make to the probe head above described numerous modifications and variations, all included in the scope of protection of the invention as defined by the following claims.

1. A probe head for testing the operation of a device under test, the probe head comprising:
a plurality of contact probes comprising a body extending along a longitudinal axis between end portions adapted to contact respective contact pads and having a substantially square or rectangular shaped cross section; and
at least one guide lying in a plane and provided with guide holes for slidingly housing the contact probes, the guide holes having a substantially square or rectangular shaped cross section,
wherein, in the plane of the guide, the cross section of the guide holes and the cross section of the contact probes housed therein are rotated relative to each other around the longitudinal axis and have respective different orientations with respect to a reference system in said plane, so that at least one edge of the body is mechanically interfering with a corresponding wall of the guide holes, and
wherein the probe head further comprises a conductive portion formed at said guide and/or formed at another guide of the probe head, said another guide comprising respective guide holes the conductive portion including at least one group of guide holes and being configured to contact and short-circuit a corresponding group of contact probes housed in said group of holes and adapted to carry a certain type of signal.

2. The probe head according to claim 1, wherein all the edges of the body are mechanically interfering with corresponding walls of the guide holes.

3. The probe head according to claim 1, wherein the cross section of the guide holes and the cross section of the contact probes have a same shape.

4. The probe head according to claim 1, wherein the guide holes are rotated with respect to the contact probes by an angle selected between 5° and 30°.

5. The probe head according to claim 1, wherein the at least one conductive portion covers at least a portion of at least one wall of the guide holes of said group of holes, the conductive portion forming a metallized portion and the edge being apt to contact the metallized portion.

6. The probe head according to claim 5, wherein the entire wall of the guide holes is covered by the conductive portion.

7. The probe head according to claim 1, wherein the guide is a lower guide of the probe head.

8. The probe head according to claim 7, further comprising an upper guide separated from the lower guide by a gap and provided with respective guide holes, the lower guide being closest to the device under test.

9. The probe head according to claim 8, wherein the lower guide and the upper guide are shifted from each other, defining an offset of a first end portion of the contact probes with respect to a second and opposite end portion of the contact probes.

10. The probe head according to claim 8, wherein the cross sections in the plane of the guide of the guide holes of the upper guide and of the contact probes have a same orientation with respect to the reference system in said plane.

11. The probe head according to claim 1, comprising a first lower guide and a second lower guide, wherein the conductive portion is formed in at least one of the first lower guide or the second lower guide, and wherein, in the plane of at least one of the first lower guide and the second lower guide, the cross section of the guide holes and the cross section of the contact probes housed therein are rotated relative to each other around the longitudinal axis and have respective different orientations with respect to the reference system in said plane, so that at least one edge of the probe body is mechanically interfering with a corresponding wall of the guide holes.

12. The probe head according to claim 1, wherein the conductive portion is arranged on a face of the guide.

13. The probe head according to claim 1, wherein the conductive portion is in the form of a plurality of metallizations which are electrically insulated from each other and configured to form a plurality of respective conductive planes for groups of the contact probes.

14. The probe head according to claim 1, wherein the guide comprises guide holes and contact probes whose cross sections are not rotated relative to each other and have a same orientation with respect to the reference system in the plane.
